(19) United States
(12) Patent Application Publication
(10) Pub. No.: US 2011/0209671 A1
(43) Pub. Date: Sep. 1, 2011

(54) Solar Actuated Pet Toy and Method of Use

(76) Inventor: Ron Forhan, Hill Air Force Base, UT (US)

(21) Appl. No.: 12/713,416

(22) Filed: Feb. 26, 2010

(51) Int. Cl. A01K 15/02; H01L 31/042

(52) U.S. Cl. 119/708; 136/244

(57) ABSTRACT

A solar powered and solar actuated pet toy designed to be attached to a window or sliding glass door. The solar powered and solar actuated pet toy will entertain a pet whenever sunlight is available, without requiring the presence or intervention of the pet owner.

### SUMMARY OF THE INVENTION

The present invention relates generally to a pet toy and more specifically to a solar powered and solar actuated pet toy designed specifically for cats but may be equally as effective for small dogs.

An increasing number of households include pets and more specifically, pets such as cats or dogs, which are considered a part of the immediate family and have unfettered access to most areas in the home. The pets may be pampered and entertained by the owners while the owners are in the house, however, there are times when the owners are required to leave the home, for work, errands and even weekends away, leaving the pets unattended. In such situations, it is common for a pet to become discontented, resentful or simply bored, and may find items in the home that can be used for their own entertainment. In most cases a pet entertaining themselves will be harmless, however, dogs are known to chew shoes, chair legs or eat the tires off the lawnmower in the garage. Cats can be equally destructive, sharpening claws on furniture, draperies or have been known to soil rugs and bedding out of what can be characterized as spite. There are myriad pet toys, both inert and electrically powered, that can be used to keep pets busy and contented. The inert toys or manually operated toys require input from the owner, dogs will fetch thrown balls, play tug-a-war with a rope or rag, and use chew toys when enticed. Cat will chase and bat simple toys such as a sting or shoelace and may be enticed with a feather or material decoy tied to the end of stick. However, as entertaining as these items are, the owner will likely tire from using the inert toy long before the pet does.

Most mechanical toys remedy the owner interaction and tiring issue; some mechanical toys will require the owner to switch them on, while other mechanical toys will include a touch or proximity sensor, allowing the pet to initiate the interaction. Most mechanical toys are electrically powered and require either a power cord or batteries for operation. Power cords can be dangerous for pets, especially when attached to a toy designed for pet interaction, while the decoy or toy itself is the intended recipient of the pets attention, a power cord attached to the toy may also move during play or provide a scent that is attractive the pet, enticing the pet to pull or chew on the power cord. In either situation the pet may be electrocuted, causing severe pain, injury or even death. Battery powered toys eliminate the dangerous power cord, however, if the toy is used regularly, the batteries will be exhausted quickly, causing the mechanical toy to slow down or stop and cause the pet to lose interest in the toy. Batteries are expensive to replace and a hazard to the environment when they are disposed of improperly. Rechargeable batteries are a partial solution but they are only effective for a limited number of charging cycles and are equally as destructive to the environment when disposed of improperly.

What is needed is a pet toy that is actuated independently of the pet owner, provides stimulation for the pet, requires no batteries and is environmentally friendly.

The present invention or solar powered and solar actuated pet toy is designed as a device that can be attached to a window frame or directly to a window or glass door and will automatically entertain a pet whenever sunlight is available. Animals habitually seek out sunlight as a place to begin their day; this is especially true during cold weather and winter months. The present invention will provide activity and help to alleviate boredom whenever the sun is shining onto the solar collector.

A first embodiment of the present invention includes a chassis or housing with an extended jib hinged at the front of the chassis, a jib line extending from the top rear of the chassis to the end of the jib and an attractor or toy extending down from the jib. A photoelectric solar collector or solar cell is attached on the back portion of the chassis. The solar cell faces away from the chassis, such that, when the device is attached to a window the solar cell is facing outward through the window, oriented to collect energy from the sun. The solar cell is directly wired to a small electric motor, so when electrical energy is available, the motor will run. Motor rpm will vary depending upon the intensity of the sun and the corresponding voltage output from the solar cell. In one embodiment, the motor is coupled to an actuator assembly through a simple pinion and bull gear transmission. In one embodiment the actuator assembly is a lobe or cam assembly that when rotated, the lobe engages the jib line, causing the jib and attached toy to rise and fall with each rotation. The resulting motion is adequate to entice and entertain most pets.

As second embodiment, includes an actuator mechanism configured as a non-concentric weight or non-concentric flywheel. This actuator may be attached directly to the electric motor or may be integrated following the transmission, however, in either configuration, as the non-concentric weight rotates, vibration will occur, which will be magnified over the length of the jib, causing the toy move in a random pattern. As the pet is enticed to bite or strike the toy with their face or paw the motion of the toy will increase.

In yet another embodiment, the actuator mechanism may be a drag-link assembly, where a rigid rod or arm is attached to the outside portion of a flywheel and then to the jib line. As the flywheel rotates, the rod will lift and then pull the jib line at a distance equal to twice the distance of the measurement between the center of the flywheel and connection point of the rigid rod to the flywheel. Manipulating the jib line causes the point of the jib and the attached toy to move a corresponding distance.

In another embodiment, the line connected to the toy may be attached directly to an outer portion of the flywheel. The line would extend from the flywheel, through a series of guides, guide holes or through the center of a hollow jib, to the point of the jib and extend downward to the toy. During each rotation the line and toy would again move equal to twice the distance of the measurement between the center of the flywheel and connection point of the line to the flywheel. It is also contemplated to attach the toy line directly to a rigid connecting rod, in a crank and piston arrangement, to manipulate the toy. This arrangement would maximize toy movement and would be mechanically robust.

In yet another embodiment, the motor is mounted at the end of the jib with the toy line attached directly to the outer portion of a flywheel or arm. This arrangement eliminates the transmission and causes the toy or target to move in a circular motion, the diameter of the circular motion is proportional to the speed of rotation.

### BRIEF DESCRIPTION OF DRAWINGS

FIG. 1—Embodiment of solar powered and solar actuated pet toy.

FIG. 2—Schematic view of a solar powered and solar actuated pet toy.

FIG. 3A—Non-concentric weight flywheel actuator.

FIG. 3B—Cam actuator.

FIG. 3C—Drag-link actuator.

FIG. 3D—Direct attachment of the toy line actuation.

FIG. 3E—Boom mounted motor and actuator configuration embodiment.

### DETAILED DESCRIPTION OF THE INVENTION

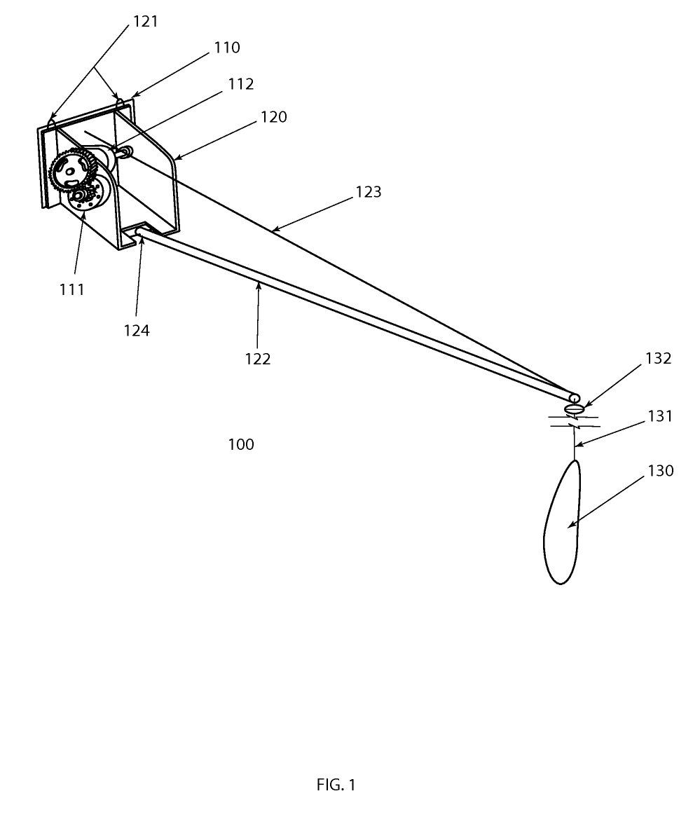

In one embodiment, solar actuated pet toy 100, FIG. 1, includes a mounting chassis 120. Mounting chassis 120 may be injection molded using, a plastic material, such as polypropylene, polyethylene, ABS or vinyl, may be cast using a metallic material such as magnesium or zinc, or may be formed using folded and spot welded sheet material such as steel or aluminum. Chassis 120 includes a hinge 124 where the jib or boom 122 is attached. Jib 122 extends away from chassis 120 and is held in an extended position by jib line 123. Jib 122 positions the attractor or toy 130 away from the mounting surface of solar actuated pet toy 100, allowing the pet to access the toy 130 from all sides or angles. Positioning the toy 130 away from chassis 120 also protects the pet if solar actuated pet toy 100 is pulled down from a mounted position. Pet toy 130 is attached to the end of jib 122 using attachment line 131. Attachment line 131 is such length that it positions the toy 130 at eye level or slightly higher of the pet anticipated to use the solar actuated pet toy 100. It is contemplated to use a break-away coupling 132 included in attachment line 131. Coupling 132 may include a magnet to magnet connection, magnet to iron connection, or may be a snap-coupling as commonly know in the art. Coupling 132 will allow the toy 130 to detach from the jib 123 with a force less than that required to remove solar actuated pet toy 100 from a mounted position.

A solar collector or solar cell 110 is attached to the rear portion of chassis 120. Solar cell 110 is electrically attached to a motor 111 and actuator mechanism 112. When sunlight shines on solar cell 110 electrical power is generated and distributed to motor 111, as motor ill turns, actuator mechanism 112 will impart motion to toy 130, either through manipulating jib 122 or by directly manipulating toy line 131, depending upon the type or configuration of actuator mechanism 112.

Solar actuated pet toy 100 may be mounted to the inside surface of a window or sliding glass door using suction cups with hooks extended through attachment loops 121. It contemplated that solar actuated pet toy 100 may also be mounted by using hooks adhesively attached to the inside surface of a window or sliding glass door, may be attached directly using a double-sided adhesive, or may be attached using a bracket designed to engage the window frame or top edge of a sliding door. In one embodiment, solar actuated pet toy 100 is mounted on a wall or vertical surface away from the window or source of solar power and having solar cell 110 remotely mounted at a source of solar power. It is also contemplated that solar actuated pet toy 100 is a free standing unit that can be placed on any flat surface, such as the floor or a low table, with solar cell 110 positioned to collect solar energy.

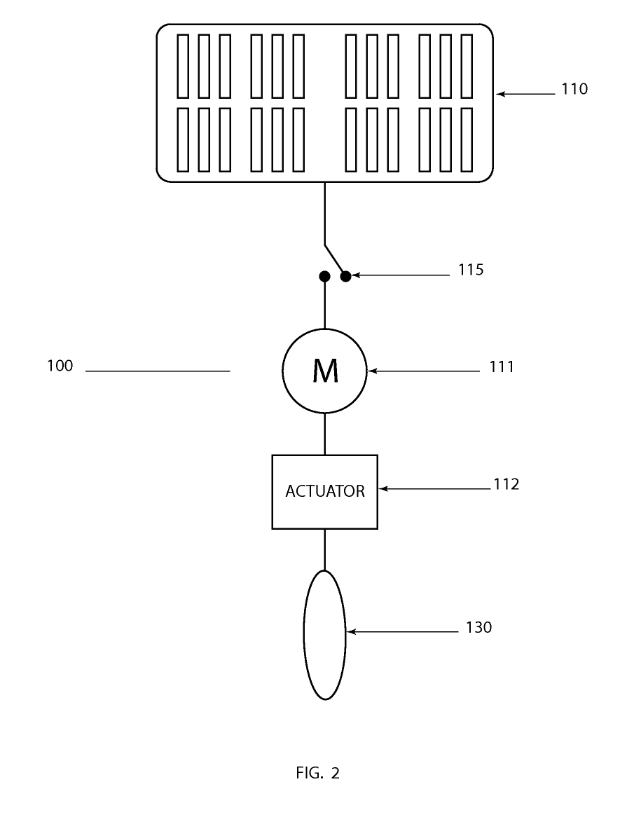

Another embodiment of solar actuated pet toy 100, with enumerated essential elements, is set forth in FIG. 2. Solar actuated pet toy 100 includes solar collector or solar cell 110, switch 115, motor 111, actuator mechanism 112 and toy 130. Solar panel 110 is electrically connected to motor 111 through switch 115. The electrical motor 1 is coupled with actuator mechanism 112 which moves or excites toy 130.

Solar cell 110 will generate a voltage when sunlight shines on the cell 110, this means when motor 111 is directly connected to solar cell 110, the motor 111 will turn and the toy 130 will be excited any time the sun shines on solar cell 110. However, there may be instances when a pet is over stimulated by the solar actuated pet toy 100 or when the pet is not in the room, the user may choose to stop the motion of the toy 130, this can be accomplished by placing switch 115 in an open position. If the pet has settled down or comes into the room where solar actuated pet toy 100 is located, the user can choose to initiate motion of toy 130 by closing switch 115.

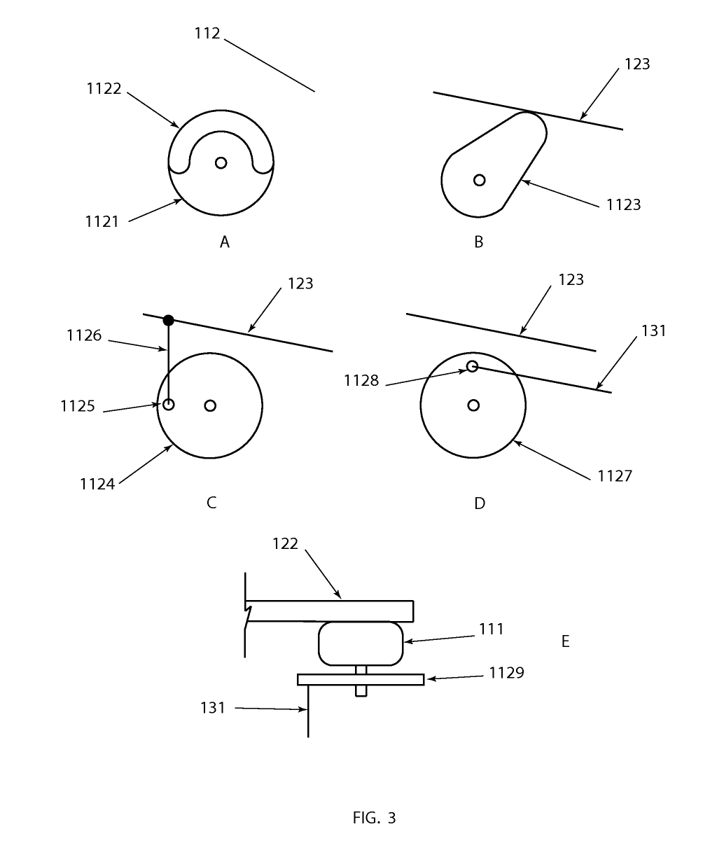

FIGS. 3A through 3E are embodiments of the actuator mechanism 112. FIG. 3A is a first embodiment where actuator mechanism 112 is a non-concentrically weighted flywheel 1121 having a weighted or thickened portion 1122. When non-concentrically weighted flywheel 1121 is rotated by motor 111 (FIGS. 1 and 2), a vibration proportional to the RPM of motor 111 is set up, the vibration will be magnified as it is translated over the length of jib 122(FIG. 1) and will cause toy 130(FIGS. 1 and 2), attached to jib 122, to move in a random pattern.

Another embodiment of actuator mechanism 112 is a lobed flywheel or cam 1123(FIG. 3B). When rotated, the lobed portion of cam 1123 will lift jib line 123(FIG. 1), this effectively shortens the working length of jib line 123, causing the point of jib 122 to rise, and lifting toy 130(FIGS. 1 and 2), as the lobed portion of cam 1123 passes jib line 123, the point of jib 122 and toy 130 will lower back to the original position. The rising and falling motion is repeated one time during each rotation of cam 1123.

Yet another embodiment, actuator mechanism is 112 is a drag-link assembly as shown in FIG. 3C. The assembly includes a flywheel 1124 with one end of a connecting rod 1125 attached to the outer portion of the flywheel 1124, the second end of connecting rod 1125 is attached to jib line 123. During rotation of flywheel 1124, connecting rod 1125 will lift and then pull jib line 123, a distance equal to twice the distance between the center of flywheel 1124 and the connecting point on the outer portion of the flywheel 1124. Again, manipulation Of jib line 123 is translated to jib 122(FIG. 1) and to toy 130(FIG. 1) attached to the end of jib 122.

Another embodiment, shown in FIG. 3D includes a flywheel 1127 with a mechanical connection point 1128 on the outer portion. Toy line 131 is attached directly to connection point 1128 in such a manner as to allow toy line 131 to be effectively lengthened and shortened, without tangling or winding, during each revolution of flywheel 1127. Toy line 131 extends to the end of jib 122(FIG. 1) and then extends down to toy 130(FIG. 1), toy line 131 is contained using guide holes, wire guides or may be routed through the center of a hollow jib 122(not shown).

In yet another embodiment, actuator mechanism 112 may be mounted on the end of jib 122(FIG. 1) as shown in FIG. 3E. Motor 111 can be moved to the end of Jib 122 and electrically connected to solar panel 110 via extended wires (not shown). A flywheel or arm 1129 is mounted directly to motor 111, toy line 131 is connected to flywheel 1129 near the outer edge or, on an outer portion, such that as flywheel 1129 rotates, the circular motion will be imparted on toy line 131 and attached toy 130(FIG. 1).

It will be obvious to those having skill in the art that many changes may be made to the details of the above-described embodiments without departing from the underlying principles of the invention. The scope of the present invention should, therefore, be determined only by the following claims.

1. A solar actuated pet toy comprising;
a chassis,
a solar panel,
a solar actuated mechanism and,
a toy attached to the solar actuated mechanism.

2. The solar actuated pet toy of claim 1, wherein the chassis includes an attachment means for a vertical surface.

3. The solar actuated pet toy of claim 2, wherein the attachment means includes suction cups, adhesive and double-sided adhesive tape.

4. The solar actuated pet toy of claim 1, wherein the chassis includes a hinged jib extending away from the chassis.

5. The solar actuated pet toy of claim 1, wherein the solar panel is mounted on a rear of the chassis.

6. The solar actuated pet toy of claim 1, wherein the solar panel is remotely mounted.

7. The solar actuated pet toy of claim 1, wherein the solar actuated mechanism is one of a cam, a non-concentric flywheel, a drag-link and a rotating arm.

8. The solar actuated pet toy of claim 1, wherein the solar actuated mechanism can be shut off using a switch.

9. The solar actuated pet toy of claim 1, wherein the toy is connected using a break-away coupling.

10. A method of using a solar actuated pet toy comprising:
mounting toy on vertical surface;
orienting a solar panel toward the sun and;
switching toy to on position.
